(19) United States
(12) Patent Application Publication
(10) Pub. No.: US 2002/0086473 A1
(43) Pub. Date: Jul. 4, 2002

(54) Process for fabricating CMOS transistor of IC devices employing double spacers for preventing short-channel effects

(76) Inventors: Wen-Jer Tsai, Hualien (TW); Tao-Cheng Lu, Kaohsiung (TW); Hung-Sui Lin, Tainan (TW); Han-Chao Lai, Taichung (TW)

Correspondence Address: Mitchell P. Brook, Baker & McKenzie, Twelfth Floor, 101 West Broadway, San Diego, CA, 92101, US

(21) Appl. No.: 09/800,758

(22) Filed: Mar. 6, 2001

(30) Foreign Application Priority Data
Jan. 3, 2001 (TW) 90100133

(51) Int. Cl. H01L 21/8238

(52) U.S. Cl. 438/199

(57) ABSTRACT

A process for fabricating CMOS transistor of IC devices that is free from short-changed effects is disclosed. The process of fabrication first forms a gate structure that has a gate polysilicon on top of a gate oxide layer on the surface of the IC substrate. A first spacer is then formed on the sidewall of the gate structure. Lightly-doped source/drain regions are then formed for the transistor by implanting impurities into the source/drain regions of the transistor. A second sidewall spacer then covers the first sidewall spacer. Heavily-doped source/drain regions underneath the lightly-doped source/drain regions are then formed by performing a source/drain implantation procedure. Finally, impurities in the lightly- and heavily-doped source/drain regions are then driven-in into the channel region of the transistor in a rapid thermal annealing procedure. The extent of lateral drive-in of the impurities into the channel region is substantially equal to the thickness of the first spacer at the root of the gate structure, and the rapid thermal annealing procedure also simultaneously activates the source/drain regions of the transistor.

### FIELD OF THE INVENTION

This invention relates in general to the fabrication of metal-oxide-semiconductor field-effect transistors (MOSFET) in integrated circuit devices. In particular, this invention relates to a process for fabricating CMOS transistors in IC devices that is free from the problem of short-channel effects.

### BACKGROUND OF THE INVENTION

In the conventional technique of the fabrication of CMOS transistors in IC and, in particular, submicron devices, the lightly-doped impurities in the source/drain regions of the transistor represent a problem. After the presence of these dopants in the source/drain regions of the transistor, the subsequent annealing in the fabrication procedural steps results in the inevitable lateral diffusion of these implants.

The annealing procedure is required for the activation of the CMOS transistor which connects the source/drain regions of the transistor to its channel. Such induced lateral diffusion, however, is somewhat undesirable as the implants may enter excessively into the channel area of the transistor if not properly controlled. Should excessive lateral diffusion of these source/drain implants occur, the direct result is a channel that is shorter than desired for the transistor. Due to reduced source-to-drain distance, a CMOS transistor with shorter-than expected channel length is subject to many problems attributable to the phenomena generally known as the short-channel effects.

For example, short-channel effects arising in a CMOS transistor that has shorter-than designed channel length would impact the device characteristics in adverse manner. The affected device characteristics include the threshold voltage, the subthreshold current, and the I-V characteristics beyond threshold, etc. This is because significant deviations from the values predicted by the long-channel model of the transistor have arisen due to the shorter-than designed channel length.

To avoid this problem, sufficient physical dimensions, that is, the channel length, of the CMOS transistor must be ensured. A minimum distance between the source and drain regions, the channel length, of the CMOS transistor is required to prevent the short-channel effects. However, scaling-down of the overall IC device is thus restricted.

It is therefore necessary to control the lateral diffusion of the source/drain implants into the channel of a CMOS transistor so as to allow for the scaling-down of the entire device as the semiconductor fabrication resolution is refined.

### SUMMARY OF THE INVENTION

It is an object of the invention to provide a process for fabricating CMOS transistor of IC devices that is free from the problem of short-channel effects.

The invention achieves the above-identified objects by providing a process for fabricating CMOS transistor of IC devices utilizing double spacers that is free from short-changed effects. The process of fabrication first forms a gate structure that has a gate polysilicon on top of a gate oxide layer on the surface of the IC substrate. A first spacer is then formed on the sidewall of the gate structure. Lightly-doped source/drain regions are then formed for the transistor by implanting impurities into the source/drain regions of the transistor. A second sidewall spacer then covers the first sidewall spacer. Heavily-doped source/drain regions underneath the lightly-doped source/drain regions are then formed by performing a source/drain implantation procedure. Finally, impurities in the lightly- and heavily-doped source/drain regions are then driven-in into the channel region of the transistor in a rapid thermal annealing procedure. The extent of lateral drive-in of the impurities into the channel region is substantially equal to the thickness of the first spacer at the root of the gate structure, and the rapid thermal annealing procedure also simultaneously activates the source/drain regions of the transistor.

### BRIEF DESCRIPTION OF THE DRAWINGS

Other objects, features and advantages of the present invention will become apparent by way of the following detailed description of the preferred but non-limiting embodiment. The description is made with reference to the accompanied drawings in which:

FIGS. 1-6 respectively depict cross-sectional views of a CMOS transistor in an IC device in the selected process steps of the fabrication process of the invention.

### DETAILED DESCRIPTION OF THE INVENTION

To achieve the object of preventing disadvantageous short-channel effects for the CMOS transistor fabricated for an IC device, a fabrication process of the invention employs an offset region at the periphery of the transistor channel region to absorb the lateral diffusion inevitable in the process of the fabrication of the device.

In accordance with a preferred embodiment of the invention, a CMOS transistor can be fabricated free from the problem of short-channel effects due to excessive lateral diffusion of source/drain implants into the channel. Such an inventive process of fabrication is described in the following paragraphs with reference to the accompanying drawings.

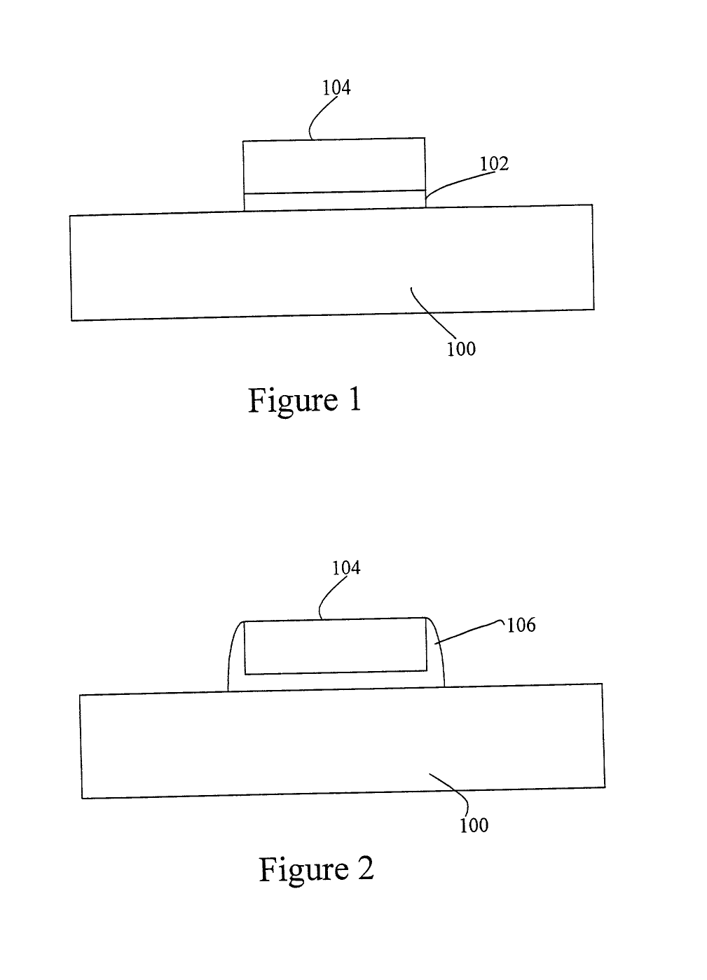

Refer to FIG. 1 of the drawing. A layer of gate oxide and a layer of gate polysilicon are subsequently formed on the substrate 100. The oxide layer may be formed, for example, by thermal oxidation of the designated area on the surface of the substrate, and the gate polysilicon layer formed by deposition. A photolithographic procedure then shapes the corresponding gate structure for the CMOS transistor, leaving the gate polysilicon 104 and the gate oxide 102 as shown in FIG. 1.

Then, in FIG. 2, a first sidewall spacer 106 is formed, for example, by deposition and then etching. The spacer 106, which may be plasma-SiO₂ formed in a PVD process followed by etching, is integrated with the gate oxide 102 and provides a sidewall isolation for the gate structure of the CMOS transistor, as is generally identified by reference numeral 106 in FIG. 2.

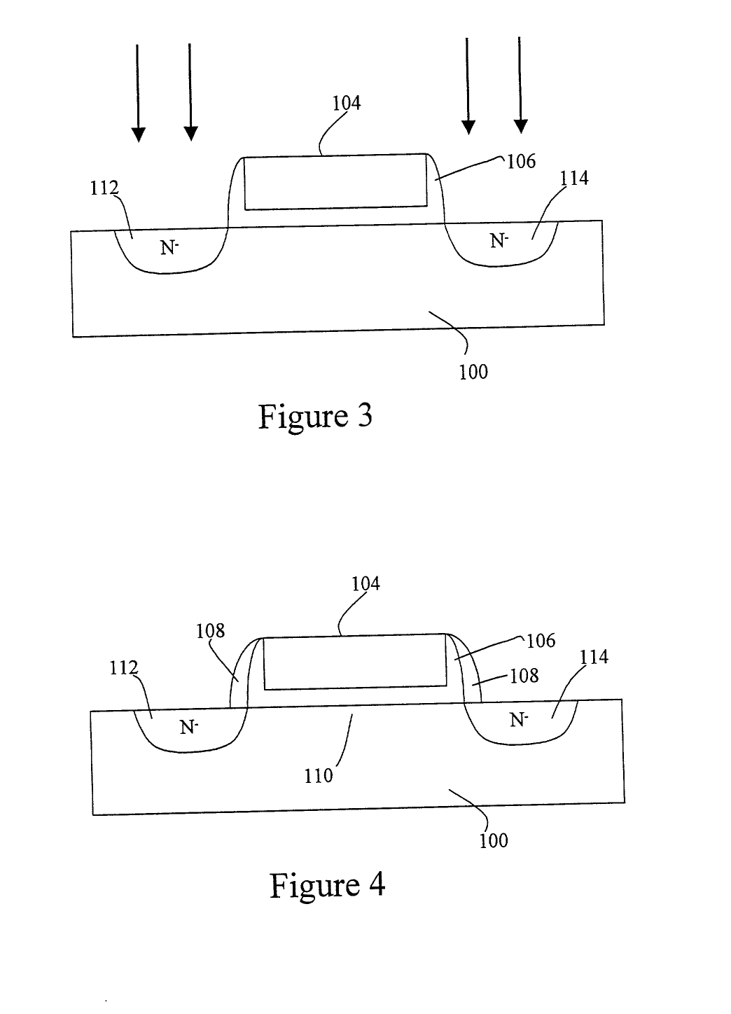

Refer next to FIG. 3. An ion implantation procedure then brings dopants into the source/drain regions. The ion implantation is a self-aligned lightly-doping process that forms lightly-doped source and drains, as is specifically indicated in the drawing as N⁻ in the source 112 and drain 114 regions. In other occasions, the ion implantation procedure that forms the source/drain regions may be one with a dosage relatively heavier than an LDD procedure.

Then, as is illustrated in FIG. 4, a second spacer 108 is formed on the sidewall of the gate structure. The second spacer 108, in effect, covers the surface of the first spacer 106 formed in the previous procedural step. This can be done, for example, by a second deposition and etching procedure.

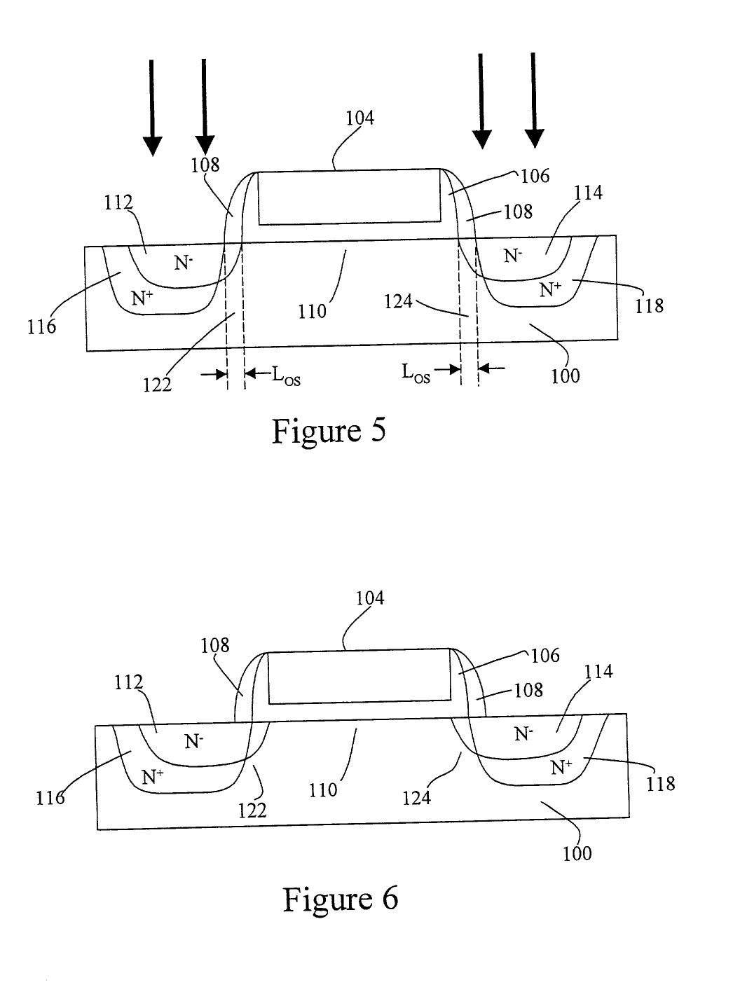

Next, in FIG. 5, an ion implantation procedure is performed to bring dopants into the source and drain regions of the CMOS transistor again. With proper control over the implantation procedure, and with the presence of the second sidewall spacer 108, regions of the source and drain of the CMOS transistor not been masked by the second spacer become heavily-doped source/drain regions 116 and 118, as is identified in the drawing by N⁺, underneath the lightly-doped regions 112 and 114 respectively Then, as is illustrated in FIG. 6, dopants in both the lightly- (112 and 114) and heavily-doped source/drain regions (116 and 118) of the CMOS transistor are brought laterally into the peripheral regions 122 and 124 of the channel 110. This can be achieved conveniently by a rapid thermal annealing (RTA) drive-in procedure. Normally, this RTA drive-in can be achieved concurrently with the thermal annealing procedure, which is required to activate the source and drain regions of the CMOS transistor.

Thus, the fabrication procedure as generally exemplified above in FIGS. 1-6 can be employed to fabricate an LDD CMOS transistor that is free from the problem of excessive lateral diffusion of the source/drain dopants into the channel region. This is the direct result of the presence of the first spacer 106 that provides offset regions along the peripheral regions 122 and 124 of the channel 110.

These offset regions in peripheral regions 122 and 124 which have a length L_{OS} in the longitudinal direction of the channel 110 of the CMOS transistor as indicated in FIG. 6, are in effect equal substantially to the thickness of the first spacer 106 at the root of the gate structure. The length L_{OS} of these offset regions, namely the thickness of the first spacer 106, can be controlled based on the requirement of the RTA process required for the activation of the source/drain regions of the CMOS transistor.

For example, the time needed to perform the source/drain activation RTA procedure can be easily translated into the extent of lateral diffusion of the LDD dopants toward the channel region of the CMOS transistor. Based on such a parameter, the thickness of the first spacer can then be determined.

Therefore, it is evident that the fabrication process of the invention is advantageous than the prior-art, as it is inherently free from the problem of short-channel effects. With an additional sidewall spacer fabrication procedure, the short-channel effect of CMOS transistors can be effectively controlled.

Although the invention has been described in considerable detail with reference to the preferred version thereof, other versions are within the scope of the present invention. For example, although CMOS transistor has been used in the described embodiment of the fabrication process of the invention, PMOS and NMOS transistors are equally applicable. Therefore, the spirit and scope of the appended claims should not be limited to the description of the preferred version contained herein.

What is claimed is:

1. A process for fabricating CMOS transistor of IC devices comprising the steps of:
a) forming a gate structure on the substrate of said IC device;
b) forming a first spacer on the sidewall of said gate structure;
c) forming lightly-doped source/drain regions for said transistor by implanting impurities into the source/drain regions of said transistor;
d) forming a second sidewall spacer for said gate structure, wherein said second sidewall spacer covering the surface of said first sidewall spacer;
e) forming heavily-doped source/drain regions underneath said lightly-doped source/drain regions by performing a source/drain implantation procedure; and
f) laterally driving-in the impurities in said lightly- and heavily-doped source/drain regions into said channel region of said transistor by performing a rapid thermal annealing procedure.

2. The process for fabricating CMOS transistor of claim 1, wherein said rapid thermal annealing procedure simultaneously activating said source/drain regions of said transistor.

3. The process for fabricating CMOS transistor of claim 1, wherein the extent of lateral drive-in of said impurities into said channel region is substantially equal to the thickness of said first spacer at the root of said gate structure.

4. The process for fabricating CMOS transistor of claim 1, wherein said first spacer is formed by first depositing a layer of silicon oxide and then etching said deposited layer of silicon oxide.

5. The process for fabricating CMOS transistor of claim 1, wherein said second spacer is formed by first depositing a layer of silicon oxide and then etching said deposited layer of silicon oxide.

6. A process for fabricating CMOS transistor of IC devices that is free from short-channel effects, said process comprising the steps of:
a) forming a gate structure comprising a gate polysilicon formed on top of a gate oxide layer on the surface of the substrate of said IC device;
b) forming a first spacer on the sidewall of said gate structure;
c) forming lightly-doped source/drain regions for said transistor by implanting impurities into the source/drain regions of said transistor;
d) forming a second sidewall spacer for said gate structure, where said second sidewall spacer covering the surface of said first sidewall spacer;
e) forming heavily-doped source/drain regions underneath said lightly-doped source/drain regions by performing a source/drain implantation procedure; and
f) laterally driving-in the impurities in said lightly- and heavily-doped source/drain regions into said channel region of said transistor by performing a rapid thermal annealing procedure; wherein
the extent of lateral drive-in of said impurities into said channel region being substantially equal to the thickness of said first spacer at the root of said gate structure.

7. The process for fabricating CMOS transistor of claim 6, wherein said rapid thermal annealing procedure simultaneously activating said source/drain regions of said transistor.

8. A process for fabricating CMOS transistor of IC devices that is free from short-channel effects, said process comprising the steps of:
a) forming a gate structure comprising a gate polysilicon formed on top of a gate oxide layer on the surface of the substrate of said IC device;
b) forming a first spacer on the sidewall of said gate structure;
c) forming lightly-doped source/drain regions for said transistor by implanting impurities into the source/drain regions of said transistor;
d) forming a second sidewall spacer for said gate structure, where said second sidewall spacer covering the surface of said first sidewall spacer;
e) forming heavily-doped source/drain regions underneath said lightly-doped source/drain regions by performing a source/drain implantation procedure; and
f) laterally driving-in the impurities in said lightly- and heavily-doped source/drain regions into said channel region of said transistor by performing a rapid thermal annealing procedure; wherein
the extent of lateral drive-in of said impurities into said channel region being substantially equal to the thickness of said first spacer at the root of said gate structure; and said rapid thermal annealing procedure simultaneously activating said source/drain regions of said transistor.

9. A process for fabricating metal-oxide-semiconductor field-effect transistor of IC devices comprising the steps of:
a) forming a gate structure on the substrate of said IC device;
b) forming a first spacer on the sidewall of said gate structure;
c) forming source/drain regions for said transistor by implanting impurities into the source/drain regions of said transistor;
d) forming a second sidewall spacer for said gate structure, wherein said second sidewall spacer covering the surface of said first sidewall spacer;
e) forming heavily-doped source/drain regions underneath said lightly-doped source/drain regions by performing a source/drain implantation procedure; and
f) laterally driving-in the impurities in said lightly- and heavily-doped source/drain regions into said channel region of said transistor by performing a rapid thermal annealing procedure.

10. The process for fabricating metal-oxide-semiconductor field-effect transistor of claim 9, wherein the source/drain regions formed in step c) are light-doped source/drain regions.

11. The process for fabricating metal-oxide-semiconductor field-effect transistor of claim 9, wherein said transistor is CMOS transistor.

12. The process for fabricating metal-oxide-semiconductor field-effect transistor of claim 9, wherein said transistor is PMOS transistor.

13. The process for fabricating metal-oxide-semiconductor field-effect transistor of claim 9, wherein said transistor is NMOS transistor.
